(19) United States
(12) Patent Application Publication
(10) Pub. No.: US 2026/0282484 A1
(43) Pub. Date: Sep. 17, 2026

(54) CONFINED BACKSIDE CONTACT

(71) Applicant: International Business Machines Corporation, Armonk, NY (US)

(72) Inventors: HUIMEI ZHOU, Albany, NY (US); Ravikumar Ramachandran, Pleasantville, NY (US); Xiaoming Yang, Clifton Park, NY (US); Ruilong Xie, Niskayuna, NY (US); Mahender Kumar, Clifton Park, NY (US); Carl Radens, LaGrangeville, NY (US)

(21) Appl. No.: 19/077,212

(22) Filed: Mar. 12, 2025

(51) Int. Cl. H10D 64/23; H10D 30/00; H10D 30/43; H10D 62/10; H10D 84/83

(52) U.S. Cl. CPC H10D 64/251; H10D 30/43; H10D 30/502; H10D 62/121; H10D 84/832

(57) ABSTRACT

A semiconductor integrated circuit (IC) devices are described. The IC devices include a confined backside contact that includes and upper portion and a lower portion in direct contact with the upper portion. The confined backside contact may be formed by processes which may result in the formation of the upper portion and lower portion. The processes may ease possible masking, photolithography, feature placement and/or alignment challenges in the formation of backside contacts and may reduce backside contact shorting failures, thereby increasing yield of the IC devices.

### BACKGROUND

Conventional transistors, such as semiconductor IC devices, or the like, incorporate planar field effect transistors (FETs) in which current flows through a semiconducting channel between a source and a drain in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET, generally, is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which a majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for improved control of the current flow therein. In the GAA FET, the channels can take the form of nanolayers, nanosheets, or the like, which are isolated from the substrate. In the GAA FET, channel surfaces are in respective contact with the source and drain and other respective channel surfaces are in contact with and surrounded by the gate.

In an embodiment of the present disclosure, a semiconductor integrated circuit (IC) device is presented. The semiconductor IC device includes a transistor that has a plurality of channels, a gate around each of the plurality of channels, and a first source/drain (S/D) region between a first shallow trench isolation (STI) region and a second STI region. The semiconductor IC device includes a retained semiconductor substrate structure below the transistor. The semiconductor IC device includes a confined backside contact. The confined backside contact includes an upper portion in direct contact with the retained semiconductor substrate structure and in direct contact with the first S/D region and a lower portion in direct contact with the upper portion.

In an embodiment of the present disclosure, another semiconductor IC device is presented. The semiconductor IC device includes a retained semiconductor substrate structure and a first isolation region comprising a first shallow trench isolation (STI) region and a first portion of a backside dielectric layer in direct contact with a backside of the first STI region. The semiconductor IC device includes a second isolation region comprising a second STI region and a second portion of the backside dielectric layer in direct contact with a backside of the second STI region. The first STI region and the second STI region have etch selectivity to the backside dielectric layer. The semiconductor IC device includes a confined backside contact that includes an upper portion in direct contact with the retained semiconductor substrate structure, in direct contact with the first STI region, and in direct contact with the second STI region and a lower portion in direct contact with the first backside isolation region and in direct contact with the second backside isolation region.

In an embodiment of the present disclosure, another semiconductor IC device is presented. The semiconductor IC device includes an isolation region between a first transistor and a second transistor. The isolation region includes a shallow trench isolation (STI) region and a dual-layered dielectric region in direct contact with a backside of the first STI region. The semiconductor IC device includes a confined backside contact that has an upper portion in direct contact with a sidewall of the first STI region and wherein a backside surface of the upper portion is substantially coplanar with a backside surface of the STI region and a lower portion in direct contact with a sidewall of the dual-layered dielectric region and in direct contact with the backside of the upper portion.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts cross section views of a semiconductor IC device that includes a confined backside contact, according to one or more embodiments of the disclosure.

FIG. 2 depicts a partial structure top-down view of an illustrative semiconductor IC device, according to one or more embodiments of the disclosure.

FIG. 3 through FIG. 7 depict respective cross section fabrication views of a semiconductor IC device that includes a confined backside contact, according to one or more embodiments of the disclosure.

FIG. 8 depicts a flowchart of a method of fabricating a semiconductor IC device that includes a confined backside contact, according to one or more embodiments of the disclosure.

FIG. 9 through FIG. 13 depict respective cross section fabrication views of a semiconductor IC device that includes a confined backside contact, according to one or more embodiments of the disclosure.

FIG. 14 depicts a flowchart of a method of fabricating a semiconductor IC device that includes a confined backside contact, according to one or more embodiments of the disclosure.

### DETAILED DESCRIPTION

The present disclosure relates to fabrication methods and resulting structures for semiconductor devices. More specifically, the present disclosure relates to fabrication methods and resulting semiconductor integrated circuit (IC) devices that include one or more confined backside contacts.

The flowcharts and cross-sectional diagrams in the drawings illustrate a method of fabricating semiconductor IC device, such as a processor, filed programmable gate array (FPGA), memory module, or the like. In some alternative implementations, the fabrication steps may occur in a different order that that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planFarization (CMP), and the like. Semiconductor doping is the modification of electrical properties by doping, for example, transistor sources and drains, by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, for some transistor architectures, integration of the transistors with a backside back end of line (BEOL) network is one of the key challenges to providing increasing packaged IC device densities and performance increases. By incorporating the BEOL network into the semiconductor IC device, there may be a logical and/or functional separation between electrical signal routing and electrical power routing through the semiconductor IC device which may ease routing congestion in some applications. Currently, there is difficulty in the formation of backside contacts that connect respective regions of the semiconductor IC device to the backside BEOL network. Particularly, there is difficulty to properly place or align the backside contacts in their formation. The embodiments of the disclosure are directed to confined backside contacts formed by techniques that may ease alignment difficulties, which may reduce the propensity of electrical shorting due to misalignment.

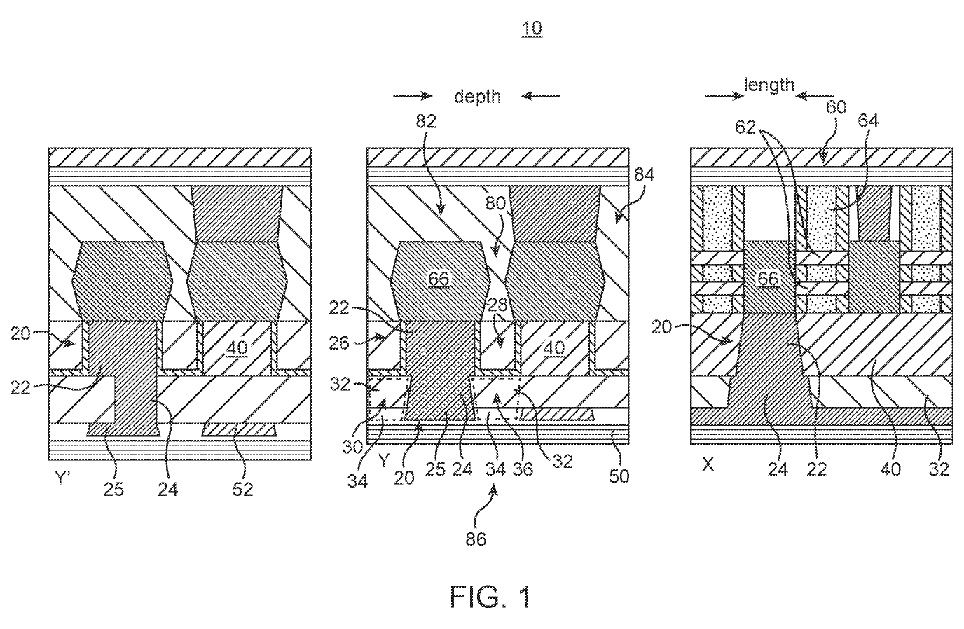

FIG. 1 depicts cross section views of a semiconductor IC device 10 that includes a confined backside contact 20, according to one or more embodiments of the disclosure. The semiconductor IC device 10 includes a transistor 60 that has a plurality of channels 62, a gate 64 around each of the plurality of channels 62, and a first source/drain (S/D) region 66 between a first shallow trench isolation (STI) region 26 and a second STI region 28. The semiconductor IC device 10 further includes a retained semiconductor substrate structure 40 below the transistor and a confined backside contact 20. The confined backside contact 20 includes an upper portion 22 in direct contact with the retained semiconductor substrate structure 40 and in direct contact with the first S/D region 36. The lower portion 24 is in direct contact with the upper portion 22. In a particular example, there is no interfacial resistance between the lower portion 24 and the upper portion 22.

In an example, a backside surface of the upper portion 22 is substantially coplanar with a backside surface of the retained semiconductor substrate structure 40. In an example, the backside surface of the upper portion 22 is substantially coplanar with respective backside surfaces of the first STI region 26 and the second STI region 28.

In an example, the semiconductor IC device 10 includes a first backside dielectric layer 32 upon the backside surface of the retained semiconductor substrate structure 40 and directly upon the respective backside surfaces of the first STI region 26 and the second STI region 28. In an example, the upper portion 22 is directly connected to the first STI region 26 and directly connected to the second STI region 28. In an example, the lower portion 24 is directly connected to the first backside dielectric layer 32. In an example, the lower portion 24 is in line with the upper portion 22, as depicted in the Y cross-section view. In an example, the lower portion 24 is offset from the upper portion 22, as depicted in the Y’ cross-section view. The lower portion 24 may be offset from the upper portion 22 due to managed or reduced misalignment, while providing adequate short protection of the confined backside contact 20. For example, the backside dielectric layer 32 may adequately and the confined backside contact patterning therein may adequately position the confined backside contact 20 away from a neighboring backside rail 52.

In an example, a horizontal depth of the upper portion 22 is greater than a horizontal depth of the lower portion 24 at an interface of the upper portion 22 and the lower portion 24, as depicted in the Y cross-section view. Similarly, in an example and as depicted in the X cross-section view, a horizontal length of the upper portion 22 is smaller than a horizontal length of the lower portion 24 at the interface of the upper portion 22 and the lower portion 24.

In another embodiment of the disclosure, another instance of semiconductor IC device 10 is presented. In the present embodiment, the semiconductor IC device 10 includes the retained semiconductor substrate structure 40, a first isolation region, and a second isolation region. The first isolation region includes the first STI region 26 and a first portion of the backside dielectric layer 32 in direct contact with the backside of the first STI region 26. The second isolation region includes the second STI region 28 and a second portion of the backside dielectric layer 32 in direct contact with the backside of the second STI region 28. The first STI region 26 and the second STI region 28 have etch selectivity to the backside dielectric layer 32. For example, the first STI region 26 and the second STI region 28 may be composed of one or more nitride dielectric material(s) and the backside dielectric layer 32 may be composed of an oxide dielectric material. In the present embodiment, the semiconductor IC device 10 further includes the confined backside contact 20.

In an example, the semiconductor IC device 10 further includes a backside-rail dielectric layer 34 upon the backside surface of the backside dielectric layer 32. In an example, the backside-rail dielectric layer 34 has etch selectivity to the backside dielectric layer 32. In an example, confined backside contact 20 further includes a backside rail 25 directly connected to the lower portion 24 within the backside-rail dielectric layer 34. In an example, there is no interfacial resistance across the interface of the upper portion 22 and the lower portion 24 and/or no interfacial resistance across the interface of the lower portion 24 and the backside rail 25.

In another embodiment of the present disclosure, another semiconductor IC device 10 is presented. In this embodiment, the semiconductor IC device 10 includes an isolation region 80 between a first transistor 82 and a second transistor 84. The isolation region 80 includes the STI region 28 and a dual-layered dielectric region 86 in direct contact with a backside of the first STI region 28. The semiconductor IC device 10 further includes the confined backside contact 20 that has the upper portion 22 in direct contact with a sidewall of the first STI region 28 and wherein a backside surface of the upper portion 22 is substantially coplanar with a backside surface of the STI region 28. The confined backside contact further includes the lower portion 24 in direct contact with a sidewall of the dual-layered dielectric region 86 and in direct contact with the backside of the upper portion 22.

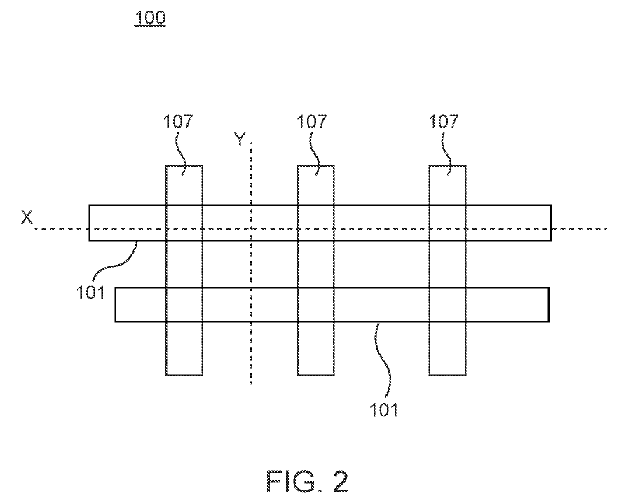

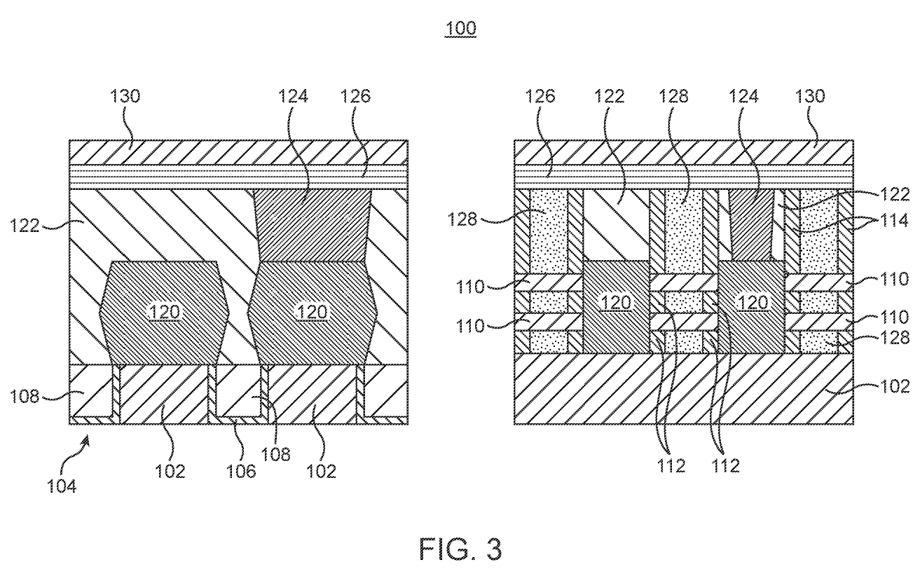

FIG. 2 depicts a partial top-down structure view of a semiconductor IC device 100 and establishes illustrative X cross-sectional plane and Y cross-sectional plane. The X cross-sectional plane is through an active region and across gate structures 107. The Y cross-sectional plane is through active regions and between adjacent gate structures 107. For clarity, the partial top-down structure views of the semiconductor IC device(s) that establish X cross-sectional plane and Y cross-sectional plane are repeated in FIG. 3 through FIG. 14, the description(s) of which are not repeated herein.

FIG. 3 depicts a cross-sectional view of the semiconductor IC device 100 after initial fabrication operations, in accordance with embodiments of the present disclosure. In these initial fabrication stages, semiconductor IC device 100 may include a substrate structure 102, shallow trench isolation regions 104, active nanolayers 110, inner spacers 112, gate spacers 114, source/drain (S/D) regions, interlayer dielectric (ILD), frontside contact(s), frontside back end of line (BEOL) network 126, and replacement gate structures 128. For clarity, the fabrication of the semiconductor IC device 100 at the present stage may utilize processes that may now be known or that may be developed in the future.

For illustration and enablement purposes, a particular fabrication process to form semiconductor IC device 100 at the present stage is presented below. This illustrative methodology may be one of many that may achieve or result in the initial semiconductor IC device 100, as depicted. When components referenced in the illustrative methodology below are depicted in FIG. 3, such associated component numeral is expressly utilized. Otherwise, when components are referenced in the illustrative methodology that are not depicted in FIG. 3, a component numeral is not denoted.

The semiconductor IC device 100 may be fabricated by providing or forming the substrate structure 102. The substrate structure 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

In another implementation, the substrate structure 102 includes an upper substrate, a lower substrate, and an insulator layer between the upper substrate and the lower substrate. The upper and lower substrates may be comprised of any other suitable material(s) than those listed above, and the insulator layer may be a dielectric layer, such as an oxide, and may be referred to as a buried oxide (BOX) substrate. In another implementation, as depicted, the substrate structure 102 includes the upper substrate, the lower substrate, and an etch stop layer between the upper substrate and the lower substrate. The etch stop layer may be a dielectric layer and may be any dielectric with etch selectivity to one or both the upper substrate and/or the lower substrate.

Nanolayers may be formed upon the substrate structure 102 by forming alternating blanket layers of sacrificial nanolayers and active nanolayers 110. In an illustrative example, each of the sacrificial nanolayers are composed of silicon-germanium (e.g., SiGe, where the Ge ranges from about 20-30%). In this manner, the active nanolayers 110 may have etch selectivity to the sacrificial nanolayers. Still further, in an illustrative example, the active nanolayers 110 are composed of silicon.

Although it is specifically contemplated that the sacrificial nanolayers can be formed from SiGe and that the active nanolayers 110 can be formed from Si, it should be understood that any appropriate materials can be used instead, as long as the two semiconductor materials have etch selectivity with respect to one another.

In certain embodiments, the sacrificial nanolayers and the active nanolayers 110 have a vertical thickness ranging, for example, from approximately 3 nm to approximately 20 nm. Although the range of 3-20 nm is cited as an example range of thickness of the sacrificial nanolayers and active nanolayers 110, other thickness of these nanolayers may be used. In certain examples, certain of the sacrificial nanolayers and active nanolayers 110 may have different thicknesses relative to one another.

The nanolayers can be deposited by any appropriate mechanism. The alternating blanket nanolayers can be epitaxially grown from one another, but alternate deposition processes, such as chemical vapor deposition (CVD), physical vapor deposition (PVD), atomic layer deposition (ALD), or gas cluster ion beam (GCIB) deposition, are also contemplated.

In a particular embodiment, the alternating blanket layers of sacrificial nanolayers and active nanolayers 110 may be epitaxially grown. The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

To form one or more nanolayer rows, a mask layer may be formed on the uppermost nanolayer. The mask layer may be comprised of any suitable mask or lithography material(s). The mask layer may be patterned and used to perform the nanolayer row patterning process. In the nanolayer row patterning process, any suitable material removal process (e.g., reactive ion etching or RIE) may be used to remove portions of the alternating nanolayers down to or into the upper substrate. As this present fabrication stage, within each nanolayer row there is alternating sacrificial nanolayers and active nanolayers 110 formed from the associated nanolayers, respectively. Subsequently, the mask layer may be removed.

The removal of undesired portion(s) of the nanolayers may further remove undesired portions the substrate structure 102 that are adjacent to respective footprints of nanolayer rows to form STI region openings. The etch may be timed or otherwise controlled to stop the removal of the substrate structure 102 such that the depth or bottom of the one or more STI region openings has a predetermined or desired dimension.

A STI region 104 may be formed within the substrate structure 102 below and adjacent to the nanolayer rows within the STI region openings. For example, one or more STI regions 104 may be formed by depositing isolation material within the STI region openings adjacent to the one or more nanolayer rows. A top surface of the one or more STI regions 104 may be at or below a top surface of upper substrate. The STI regions 104 may be formed by depositing STI liner 106, such as a nitride, upon the substrate structure 102 and subsequently depositing an STI fill 108, such as an oxide upon the STI liner 106. The one or more STI regions 104 may have a volume that sufficiently electrically isolates components or features of neighboring transistors, or the like, and/or may sufficiently electrically isolate neighboring nanolayer rows.

The sacrificial gate structures may be formed by initially depositing the sacrificial gate liner layer (e.g., a dielectric, oxide, or the like) upon the one or more STI regions 104 and upon and around the one or more nanolayer rows. The sacrificial gate structures may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer rows. The sacrificial gate structures may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate, and the sacrificial gate cap, respectively, of each of the one or more sacrificial gate structures.

The gate spacer(s) 114 may be respectively formed upon the one or more STI regions 104, upon and around the one or more nanolayer rows, and upon and around each of the one or more sacrificial gate structures. In one example, gate spacers 114 may be formed of a dielectric material(s), such as such as silicon nitride, SiBCN, SiNC, SiN, SiCO, SiNOC, a combination thereof, or the like.

The one or more gate spacers 114 may be formed by a deposition of a blanket gate spacer dielectric material. Excess, undesired, and/or exposed blanket gate spacer dielectric material may be subsequently removed by a substrative removal technique, such as an etch. For example, a directional etch may remove exposed horizontal portion(s) of the blanket gate spacer dielectric material while also leaving vertical portion(s) of the blanket gate spacer dielectric material, upon the sidewall perimeter of each of the one or more sacrificial gate structures intact.

S/D canyons may be formed between adjacent sacrificial gate structures by removing respective portions of the sacrificial nanolayers and active nanolayers 110 that are between gate spacers 114 of adjacent or neighboring sacrificial gate structures. The one or more S/D canyons may be formed to a depth to stop at or within the upper substrate. The nanolayers may be removed by one or more etches that may be selective to the respective material(s) of gate spacers 114, sacrificial gate cap, and/or STI regions 104.

The retained one or more portions of one or more nanolayer rows may be such portions of the nanolayers that were protected generally below and/or internal to respective sacrificial gate structures and/or by the associated gate spacers 114 and may be referred to herein as nanolayer stacks. As such, respective sidewalls or end surfaces of the nanolayer stacks may be substantially coplanar with respective outer sidewalls of the associated gate spacers 114.

Lateral indents may be formed by a reactive ion etch (RIE) process and/or a wet etch process, which can remove portions of the sacrificial nanolayers. The etch may be selective to the active nanolayers 110, to the upper substrate, to the STI region 104, to the gate spacers 114, to the sacrificial gate cap, and/or the like. The etch can be controlled to remove the portions of the sacrificial nanolayers not covered by the sacrificial gate. For example, the horizontal depth of the indents may be chosen to set a gate length for a replacement gate structure that is formed in place of one sacrificial gate structure.

Subsequently, the indents may be filled by depositing a dielectric which may resultantly form the respective inner spacers 112 against the active nanolayers 110. The inners spacers 112 can be simultaneously formed by ALD or CVD or any other suitable deposition technique that deposits dielectric material within the indents. In some examples, the inners spacers 112 are composed of a dielectric material, such as an oxide, nitride, a combination, or the like. In other examples, the inners spacers 112 may be composed of a low-κ dielectric material (a material with a lower dielectric constant relative to SiO₂), SiN, SiO, SiBCN, SiOCN, SiCO, etc. or any other suitable dielectric material.

In certain implementations, after the formation of the inner spacers 112, an isotropic etch process may be performed to create outer vertical surfaces of the inners spacers 112 that align with or are substantially coplanar with the outer vertical surfaces of the associated gate spacers 114 there above.

Semiconductor IC device 100 may be further fabricated by forming source/drain (S/D) regions 120 within respective S/D canyons. Each S/D region 120 may form either a source or a drain, respectively, of respective one or more GAA FETs and may be connected to respective end surfaces of active nanolayers 110 and may be connected to respective end surfaces of inner spacers 112.

Each of the S/D region 120 may be composed of a semiconductor material and a dopant. Alternatively, the S/D regions 120 may be composed of a metalloid. As used herein, a “source/drain” region can be a source region or a drain region depending on subsequent wiring and application of voltages during operation of the transistor. In examples, the semiconductor material that provides each of the S/D region 120 is composed of one of the semiconductor materials mentioned above for the semiconductor structure 102 and the active nanolayers 110.

When the S/D regions 120 include a semiconductor, the dopant that is present in the S/D region 120 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous.

When the S/D regions 120 include a semiconductor, the S/D region(s) 120 may be formed by epitaxially growth within the S/D canyons. In some examples, S/D region(s) 120 are formed by in-situ doped epitaxial growth. In some embodiments, the S/D region(s) 120 epitaxial growth may overgrow above the upper surface of the semiconductor IC device 100. In some implementation, all n-type S/D regions 120 may be formed and subsequently all p-type S/D regions 120 may be formed, or vice versa.

Suitable n-type dopants include but are not limited to phosphorous (P), and suitable p-type dopants include but are not limited to boron (B). The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In preferred embodiments, the S/D epitaxial growth conditions that promote in-situ Boron doped SiGe for p-type transistor and phosphorus or arsenic doped silicon or SiC for n-type transistors.

When the S/D regions 120 include a semiconductor, in certain implementations, the S/D regions 120 may be epitaxially grown utilizing the respective surfaces of the upper substrate and the active nanolayers 110 that are exposed to the S/D canyons as the seed surface. When the S/D regions 120 include a semiconductor, the S/D region(s) 120 may be overgrown and then partially recessed such that an upper portion of the S/D region(s) 120 are removed. For example, the upper portion of the one or more S/D region(s) 120 may be etched or otherwise removed. The etch may be timed or otherwise controlled to stop the removal of S/D region(s) 120 such that the top surface of S/D region(s) 120 is above the upper surface of the topmost active nanolayer 110 so as to appropriately contact the end surface of the topmost active nanolayer 110.

For clarity, the structures and fabrication methodology of semiconductor IC device 100 may enable the absence of a backside contact placeholders underneath the S/D regions 120. For example, a backside contact placeholder need not be formed within the S/D canyons prior to the S/D region(s) 120 being formed.

A frontside ILD 122 may be formed upon the one or more source/drain (S/D) regions 120 and upon at least the sidewalls of the sacrificial gate structures and may be further formed upon the STI regions 104. The ILD 122 may be formed by depositing a dielectric material, such as, for example, porous silicates, carbon doped oxides, silicon dioxides, silicon nitrides, silicon oxynitrides, or other dielectric materials. Any manner of forming the ILD 122 can be utilized. The ILD 122 can be formed using, for example, CVD, PECVD, ALD, flowable CVD, spin-on dielectrics, or PVD.

In an example, the ILD 122 may be formed to a thickness above the top surface of the sacrificial gate structures. Subsequently, a planarization process, such as a CMP, may be performed to remove the sacrificial gate cap, to partially remove the excess ILD 122, and to partially remove the gate spacers 114. The planarization may partially remove some of the sacrificial gate or may at least expose the sacrificial gate of the sacrificial gate structures. The CMP may create a planar or horizontal top surface for the semiconductor IC device 100. In other words, the respective top surfaces of ILD 122, gate spacers 114, sacrificial gates may be coplanar.

The sacrificial gate structure may be removed by initially removing the sacrificial gate and sacrificial gate oxide by a removal technique, such as one or more series of etches. For example, such removal may be accomplished by an etching process. Appropriate etchants may be used that remove the sacrificial gate and/or sacrificial gate oxide selective to the active nanolayers 110, gate spacers 114, inner spacers 112, or the like.

The active nanolayers 110 may be released by removing the sacrificial nanolayers. The sacrificial nanolayers may be removed by a removal technique, such as one or more series of etches. For example, the etching can include a wet chemical etching process in which one or more chemical etchants are used to remove the sacrificial nanolayers. Appropriate etchants may be used that remove the sacrificial nanolayers selective to the active nanolayers 110, the inner spacers 112, gate spacers 114, or the like. After the removal of sacrificial nanolayers, void spaces may exist between the active nanolayers 110.

For clarity, the removal of at least the sacrificial gate and the sacrificial nanolayers generally form a replacement gate structure opening. A particular replacement gate structure 128 may be formed around the active nanolayers 110 within one replacement gate structure opening.

Replacement gate structure(s) 128 may be formed by initially forming an interfacial layer (not shown) on the interior surfaces of the gate structure opening (e.g., interior surfaces of gate spacer 114, the interior surfaces of the active nanolayers 110 and interior surfaces of inner spacers 112. Then, a high-κ layer may be formed to cover the surfaces of exposed surfaces of the interfacial layer. The high-κ layer can be deposited by any suitable techniques, such as ALD, CVD, metal-organic CVD (MOCVD), physical vapor deposition (PVD), thermal oxidation, combinations thereof, or other suitable techniques. A high-κ dielectric material is a material with a higher dielectric constant than that of SiO₂, and can include e.g., LaO, AlO, ZrO, TiO, Ta₂O₅, Y₂O₃, SrTiO₃(STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The high-κ layer can include a single layer or multiple layers, such as metal layer, liner layer, wetting layer, and adhesion layer.

Replacement gate structure(s) 128 may be further formed by depositing a work function metal (WFM) gate upon the high-κ layer. The WFM gate can be comprised of metals, such as, e.g., copper (Cu), cobalt (Co), aluminum (Al), platinum (Pt), gold (Au), tungsten (W), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In various exemplary embodiments, the height of the WFM gate can be reduced by chemical-mechanical polishing (CMP) and/or etching. Therefore, the planarization process can be provided by CMP. Other planarization process can include grinding and polishing. In general, the work function metal (WFM) gate sets the threshold voltage (Vt) of the device. The high-κ layer separates the WFM gate from the nanolayer channel (i.e., active nanolayers 110). Other metals that may be desired to further fine tune the effective work function (eWF) and/or to achieve a desired resistance value associated with current flow through the gate in the direction parallel to the plane of the nanolayer channel.

The one or more replacement gate structures 128 may be further formed by depositing a conductive fill gate upon the WFM gate. The conductive fill gate can be comprised of metals, such as but not limited to, e.g., tungsten, aluminum, ruthenium, rhodium, cobalt, copper, tantalum, titanium, carbon nanowire materials including graphene, or the like. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the replacement gate structure 128 formation, the top surface of the semiconductor IC device 100 may be planarized by a planarization technique such as a CMP, mechanical grinding process, or the like. After the planarization technique, respective top surfaces of the ILD 122, gate spacers 114, replacement gate structure(s) 128, may be horizontal and/or may be at least substantially coplanar.

A frontside contact frontside ILD may be formed upon respective top surfaces of replacement gate structures 128, ILD 122, and gate spacers 114. The frontside contact frontside ILD may be formed by depositing a dielectric material, such as, for example, porous silicates, carbon doped oxides, silicon dioxides, silicon nitrides, silicon oxynitrides, or other dielectric materials. The material of the frontside contact frontside ILD may be the same as the material of the ILD 122, as depicted. Alternatively, the frontside contact frontside ILD may be a relatively different dielectric material than the dielectric material of ILD 122.

The frontside contacts 124 may be formed by patterning respective frontside contact openings within the frontside ILD , the frontside contact frontside ILD , respectively, from the frontside (i.e., from above the semiconductor IC device 100, as depicted, downward to respective structures thereof). The frontside contacts 124 may be in direct or indirect physical and electrical contact with respective material(s) of one or more regions of the semiconductor IC device 100.

The frontside contacts 124 may be formed by depositing conductive material such as metal into the respective frontside contact opening(s). In an example, frontside contacts 124 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, and the conductive fill. In embodiments, the frontside contacts 124 are fabricated in middle-of-line (MOL) fabrication operations and may be illustrations of MOL contacts.

The frontside back end of line (BEOL) network 126 may be formed and a carrier wafer 130 may be bonded to the frontside BEOL network 126. In the semiconductor IC device fabrication industry, there are three sections referred to in a build: front-end-of-line (FEOL), BEOL, and the section that connects those two together, the MOL. The FEOL is made up of devices, e.g., transistors, the BEOL is made up of interconnects and wiring, and the MOL includes interconnects between the FEOL and BEOL and material to prevent the diffusion of BEOL conductive material(s) to the FEOL devices.

The BEOL section is the portion of IC fabrication where the individual devices (e.g., transistors, capacitors, resistors, etc.) become interconnected with wiring on the semiconductor IC device, e.g., the metallization layer or layers of a wafer. The BEOL section includes contacts, insulating layers (dielectrics), metal levels, and bonding sites for chip-to-package connections. In the BEOL section, part of the fabrication stage contacts (pads), interconnect wires, vias and dielectric structures are formed. For modern IC processes, more than one metal layers may be added in the BEOL section.

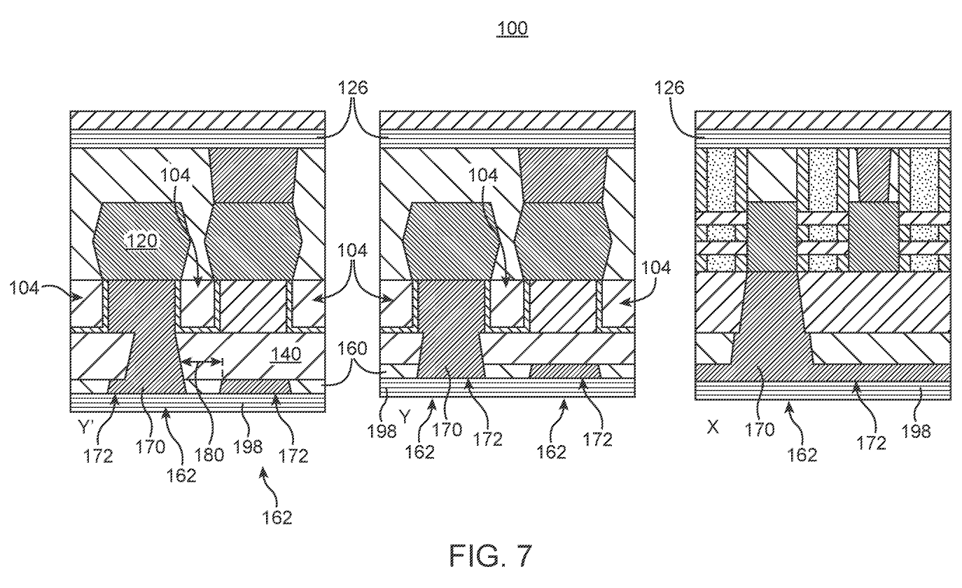

In the present example, there are multiple BEOL levels each on opposites sides of the semiconductor IC device 100. First, a frontside BEOL network 126 is formed on the frontside of the semiconductor device 100. Subsequently, a backside BEOL network 198, as depicted in FIG. 7, may be formed.

In the depicted example, the frontside BEOL network 126 is formed over the frontside contact frontside ILD and upon the frontside contacts 124. Respective wires within the frontside BEOL network 126 may be electrically connected to the one or more S/D regions 120, to the one or more replacement gate structure(s) 128, or the like, by a respective frontside contact 124. For example, respective wire(s) within the frontside BEOL network 126 may be electrically connected to an appropriate S/D region 120 by a frontside contact 124 and another and different group of respective wire(s) within the frontside BEOL network 126 may be electrically connected to an appropriate replacement gate structure 128 by a different frontside contact 124, etc.

The frontside BEOL network 126 can include one or more interconnect dielectric material layers (including one of the dielectric materials mentioned above for the frontside ILD ) and contains conductive wires (the conductive wires can be composed of any electrically conductive material, metal, electrically conductive metal alloy, or the like) embedded therein. In some embodiments, the frontside conductive wires within the frontside BEOL network 126 are composed of Cu. The frontside BEOL network 126 can include “x” numbers of frontside metal levels, wherein “x” is an integer starting from 1. The frontside BEOL network 126 may further contain conductive pads that are connected to one or more of the conductive wires and may be used to connect the semiconductor IC device 100 to an external and/or higher-level structure, such as a chip carrier, motherboard, or the like.

The illustrated semiconductor IC device 100 may be further fabricated by bonding carrier wafer 130 to the frontside BEOL network 126. The carrier wafer 130 can include one of the semiconductor materials mentioned above for the semiconductor structure and the carrier wafer 130 may be attached to the semiconductor IC device 100 by a wafer-to-wafer bonding technique.

In examples, the semiconductor IC device 100 may be further fabricated by recessing the substrate structure with appropriate substrative removal techniques, such as one or more series of etches. The one or more etches may be timed or otherwise controlled to remove the material of bottom substrate and may utilize the etch stop layer as an etch stop. The etch stop layer may be removed by appropriate substrative removal techniques, such as one or more series of etches. The one or more etches may be timed or otherwise controlled to remove the material etch stop layer and may utilize the upper substrate as an etch stop. For clarity, semiconductor IC device 100 retains portions of the substrate structure 102, which may be generally between STI regions 104. In a particular embodiment, the backside of the semiconductor IC device 100 may undergo a CMP or other planarization process. Subsequently, the respective backsides of the substrate structure 102 and the STI regions 104 may be substantially coplanar and/or substantially horizontal.

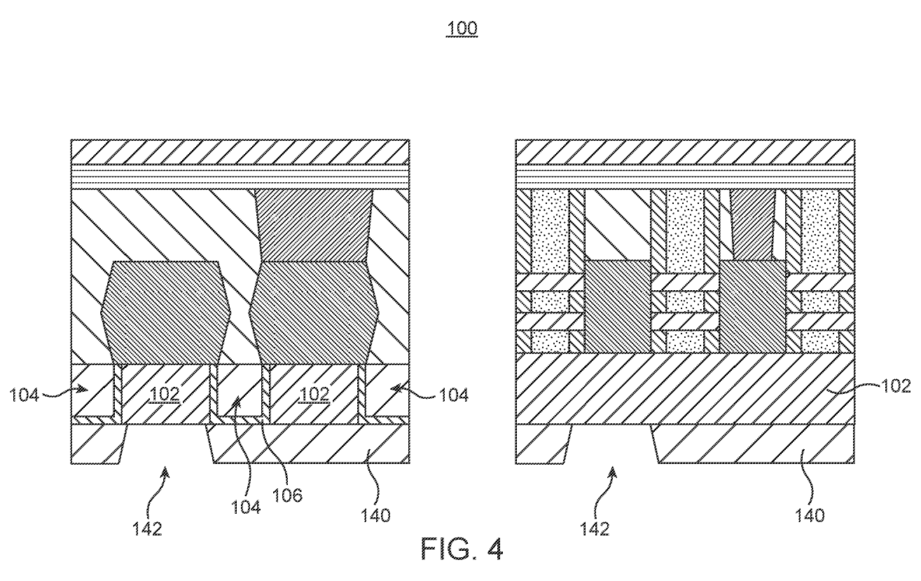

FIG. 4 depicts cross-sectional views of the semiconductor IC device 100 after fabrication operations, in accordance with embodiments of the present disclosure. In the depicted fabrication stages, a first backside contact layer 140 may be formed and patterned.

The first backside contact layer 140 may be formed by depositing a dielectric layer over the backside of the semiconductor IC device 100. The first backside contact layer 140 can be any suitable dielectric material, such as, for example, porous silicates, carbon doped oxides, silicon dioxides, silicon nitrides, silicon oxynitrides, or other dielectric materials. In a particular example, the first backside contact layer 140 may consist of a dielectric material with etch selectivity relative to the material(s) of the STI regions 104 and/or the substrate structure 102. For example, the material(s) of the STI regions may be nitride based, the material of the substrate structure 102 may be silicon, and the material of the first backside contact layer 140 may be silicon oxide based.

Subsequently, first backside contact layer 140 may be patterned to form backside contact placeholder openings 142. The backside contact placeholder openings 142 may be formed by lithography and etch process(es). In such process(es), a mask (not shown) may be applied to the backside of the first backside contact layer 140 and patterned. Openings in the patterned mask may sequentially expose respective portions of the underlying upper substrate portions while other protected portions of semiconductor IC device 100 may be protected and retained. The backside contact placeholder openings 142 may be located in each and every location in line with a S/D region 120 to which a frontside contact 124 is not connected.

The etch that forms the backside contact placeholder openings 142 may be controlled so that the well surface of the backside contact placeholder openings 142 is at least exposes the underlying substrate structure 102, as depicted. For clarity, the formation of backside contact placeholder openings 142 may expose or otherwise gouge the backside of the underlying substrate structure 102 that is associated therewith.

The etch that forms the backside contact placeholder openings 142 may be selective to the substrate region 102 and inset within adjacent STI regions 104, as depicted. For example, the etch may remove the material of upper substrate selective to the material of the substrate region 102. As such, the STI liner 106 and/or STI fill 108 of the neighboring STI regions 104 may substantially remain subsequent to the formation of the backside contact placeholder openings 142.

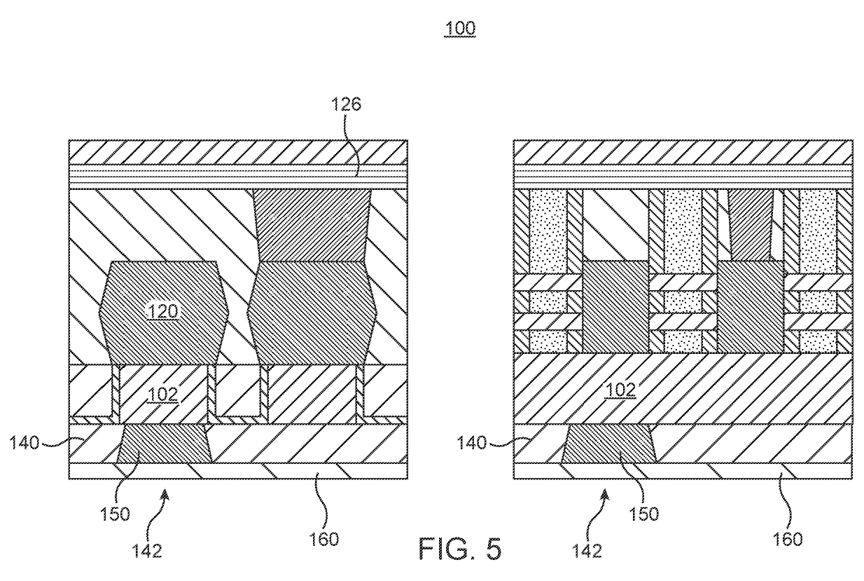

FIG. 5 depicts cross-sectional views of the semiconductor IC device 100 after fabrication operations, in accordance with embodiments of the present disclosure. In the depicted fabrication stages, backside contact placeholder 150 may be formed and a second backside contact layer 160 may be formed.

The illustrated semiconductor IC device 100 may be further fabricated by forming a respective backside contact placeholder 150 within the backside contact placeholder openings 142 and upon the exposed respective portions of the substrate structure 102. In one example, a respective backside contact placeholder 150 may be formed in each location(s) underneath associated S/D regions 120 that are not connected to the frontside BEOL network 126.

A respective backside contact placeholder 150 may be formed by epitaxially growing an epitaxial material from exposed substrate structure 102 surface(s) within the backside contact placeholder openings 142. Because the backside contact placeholder 150 are formed after the associated S/D region 120, the present fabrication sequence may be referred to as backside contact placeholder last sequence.

In some embodiments, epitaxial growth and/or deposition processes may be selective to forming on the semiconductor surfaces of the upper substrate 102, and may not form from dielectric surfaces, such as silicon dioxide or silicon nitride surfaces. In some embodiments, the epitaxial growth of the one or more backside contact placeholders 150 may overgrow above the backside surface of the first backside contact layer 140.

In an example, the epitaxial material of the one or more backside contact placeholders 150 may be chosen to be etch selective to the material of the S/D region(s) 120 (e.g., the same type of material as the substrate structure 102). For example, the one or more backside contact placeholders 150 may be Sie and substrate structure 102 may be Si and the backside contact placeholders 150 may be epitaxially grown from the backside surface of the substrate structure 102.

The backside contact placeholders 150 may be overgrown and then partially recessed such that the backside surface of the backside contact placeholders 150 may be substantially coplanar with and/or substantially horizontal with the backside surface of the first backside contact layer 140. For example, a backside portion of the backside contact placeholders 150 may be etched or a CMP may be utilized to planarize the backside surface of the semiconductor IC device 100.

For clarity, the backside contact placeholders 150 may be self-aligned to the substrate structure 102, there above, as a result of the epitaxial formation therefore, and may therefore reduce subsequent alignment concerns during the formation of the associated confined backside contact.

The semiconductor IC device 100 may be further fabricated by forming a second backside contact layer 160. The second backside contact layer 160 may be formed by depositing a dielectric layer over the backside of the semiconductor IC device 100. The second backside contact layer 160 can be any suitable dielectric material, such as, for example, porous silicates, carbon doped oxides, silicon dioxides, silicon nitrides, silicon oxynitrides, or other dielectric materials. In a particular example, the second backside contact layer 160 may consist of a dielectric material with etch selectivity relative to the material(s) of the backside contact placeholders 160 and/or the first backside contact layer 140. For example, the material of the first backside contact layer 140 may be silicon oxide based and the material of the second backside contact layer 160 may be XYZ.

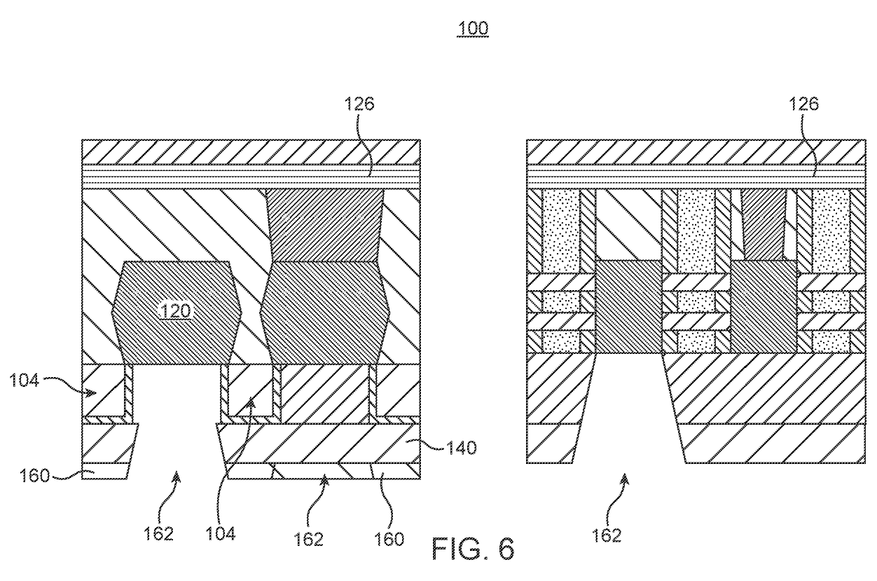

FIG. 6 depicts cross-sectional views of the semiconductor IC device 100 after fabrication operations, in accordance with embodiments of the present disclosure. In the depicted fabrication stages, second backside contact layer 160 may be patterned and confined backside contact openings 162 may be formed.

The second backside contact layer 160 may be patterned to form confined backside contact openings 162. The confined backside contact openings 162 may be formed by lithography and etch process(es). In such process(es), a mask (not shown) may be applied to the backside of the second backside contact layer 160 and patterned. Trenches in the patterned mask may sequentially expose respective portions of the underlying respective portion(s) of various backside contact placeholders 150, while other protected portions of semiconductor IC device 100 may be protected and retained.

Due to the second backside contact layer 160 relatively later fabrication sequence stage and increased pitch between adjacent confined backside contact openings 162, alignment of such trenches may be relatively improved. The etch that forms the confined backside contact openings 162 may be controlled so that the well surface of the confined backside contact openings 162 is at least exposes the underlying backside contact placeholder(s) 150. For clarity, the formation of confined backside contact openings 162 may expose or otherwise gouge the backside of the underlying backside contact placeholder(s) 150 that are associated therewith.

The confined backside contact openings 162 may be further formed by etch process(es) that may remove the exposed backside contact placeholder(s) 150 and associated substrate structure 102 regions. In such process(es), etching processes can have etching parameters that can be tuned, such as etchants used, etching temperature, etching solution concentration, etching pressure, source power, RF bias voltage, RF bias power, etchant flow rate, to promote desired material removal and desired material retention. For example, the confined backside contact openings 162 may formed by removing the appropriate backside contact placeholders 150 and the substrate structure 102 regions selective to the material of the STI region(s) 104 and to the associated S/D region 120. For clarity, when associated or otherwise in line with a respective backside contact placeholder(s) 150, the confined backside rail trench 162 fabrication process result in the exposing of the associated S/D region(s) 120. Further, for clarity, in other locations when not associated or otherwise in line with a respective backside contact placeholder(s) 160, the confined backside rail trench 162 fabrication process may result in the confined backside rail trench 162 being substantially confined to the second backside contact layer 160. For example, in locations that are in line with a S/D region 120 that is connected to the frontside BEOL network 126, the confined backside rail trench 162 fabrication process results in the confined backside rail trench 162 being substantially confined within the second backside contact layer 160 and against the backside surface of the first backside contact layer 140.

FIG. 7 depicts cross-sectional views of the semiconductor IC device 100 after fabrication operations, in accordance with embodiments of the present disclosure. In the depicted fabrication stages, confined backside contacts 170 may be formed and backside BEOL network 198 may be formed.

The confined backside contacts 170 may be formed within a respective backside contact opening 162 against the associated S/D region 120. The confined backside contacts 170 may be formed by depositing conductive material, such as metal, within the backside contact openings 162. In an example, multiple confined backside contacts 170 may be formed by depositing a liner, such as Ni, NiPt or Ti, etc. onto the backside of semiconductor IC device 100 and into the backside contact openings 162, depositing an adhesion liner, such as TiN, TaN, etc. upon the liner, and by depositing a conductive fill, such as Al, Ru, W, Co, Cu, etc. upon the adhesion liner.

Subsequently, a planarization process, such as a CMP, may expose a backside surface of the second backside contact layer 160 and the backside rail 172 portion of the confined backside contact 170. As a result, the respective bottom surfaces of confined backside contacts 170 (e.g., the backside surface of the backside rail 172, etc.) and the second backside contact layer 160 may be substantially horizontal and/or substantially coplanar.

The backside BEOL network 198, such as a backside power distribution network (BSPDN) may be formed upon the confined backside contacts 170, upon the second backside contact layer 160, etc. The backside BEOL network 198 may include signal wires for signal routing and power wires for providing power potential (e.g., VDD, VSS, etc.). For example, the backside BEOL network may have a one or more wires that may be connected to both a first backside rail 172 and a second one or more wires that may be connected to both a second backside rail 172.

The backside BEOL network 198 may allow for the distribution of power wires and signal wires between both the frontside and backside of the semiconductor IC device. The backside BEOL network 198 may further allow for the full or partial decoupling of signal routing and/or power routing and/or allows for dividing or splitting power wires and/or signal wires between both the frontside BEOL network 126 and the backside BEOL network 198. By also incorporating the backside BEOL network 198, wire and contact routing congestion may be reduced, which may lead to further semiconductor IC device 100 scaling. For example, semiconductor IC devices that incorporate a backside BEOL network can result in a 30% area reduction and improved current-resistance (IR) drop compared to typical semiconductor IC devices that include solely a frontside BEOL network.

The backside BEOL network 198 may be electrically connected to the one or more S/D regions 120 by way of a particular confined backside contact 170 . For example, a first backside wire within the backside BEOL network 198 may be electrically connected a first S/D region 120 by way of a first confined backside contact 170 and a second backside wire within the backside BEOL network 198 may be electrically connected a second S/D region 120 by way of a second confined backside contact 170.

The backside BEOL network 198 can include one or more interconnect dielectric material layers and contains backside conductive wires and/or interconnects, such as VIAs, embedded therein. In some embodiments, the backside wires within the backside BEOL network 198 are composed of Cu. The backside BEOL network 198 can include “x” numbers of backside metal levels, wherein “x” is an integer starting from 1. If not included in frontside BEOL network 126, backside BEOL network 198 may further contain conductive pads that are connected to one or more of the backside metal wires and may be used to connect the semiconductor IC device 100 to the external and/or higher-level structure.

In an example, signal routing and power routing is effectively split between the frontside BEOL network 126 and the backside BEOL network 198. For example, at least 90% of the frontside metal wires (e.g., furthest from the depicted transistors) are signal routing metal wires and the remainder frontside metal wires which are usually present in metal levels closest to the transistors, can be used as power routing wires. Further in this example, at least 90% of the backside metal wires that are in metal levels closest to the backside contacts are power routing metal wires. Power routing wires may be less dense than signal routing wires. A signal routing wire is defined herein as a conductive feature, such as a wire, interconnect, or the like, that is configured to carry or have a functional or logical potential or signal that is used to at least partially accomplish a computing task. A power routing wire is defined herein as a conductive feature, such as a wire, trace, plane, or the like, that is configured to electrically carry power potential. For example, a power routing wire carries or otherwise has a functional power potential, such as VDD, VSS, or the like.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

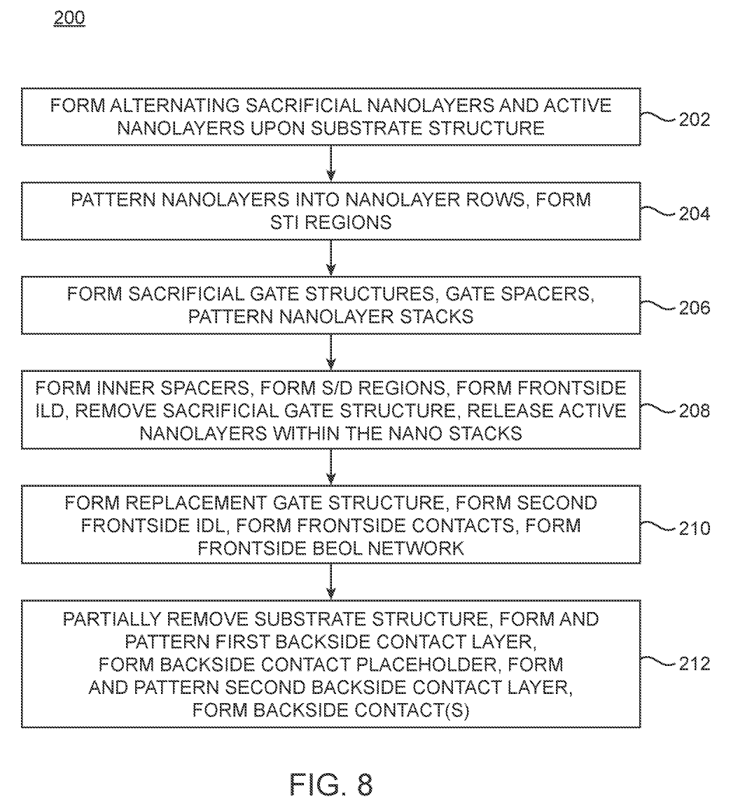

FIG. 8 depicts a flow diagram illustrating method 200 to fabricate a semiconductor IC device, such as semiconductor IC device 100. The depicted fabrication operations of method 200 are illustrated and described above with reference to one or more of FIG. 3 through FIG. 7 of the drawings, which describe the fabrication of semiconductor IC device 100, though the fabrication operations described in method 200 may be used to fabricate other types of semiconductor IC devices. The method 200 depicted herein is illustrative. There can be many variations to the diagram or operations described therein without departing from the spirit of the embodiments. For instance, the operations can be performed in a differing order, or operations can be added, deleted, or modified.

At block 202, method 200 may begin with forming alternating sacrificial nanolayers and active nanolayers 110 the substrate structure 102. At block 204, method 200 may continue with patterning the nanolayers into nanolayer rows and with forming STI regions 104 between the nanolayer rows. At block 206, method may continue with forming sacrificial gate structures, with forming gate spacers 114, and with patterning the nanolayer rows into nanolayer stacks.

At block 208, method 200 may continue with indenting the sacrificial nanolayers within the nanolayer stacks and with forming inner spacers 112 within the associated void formed by the partial removal of the sacrificial nanolayers. Further at block 208, method 200 may continue with forming S/D regions 120, with forming ILD 122, with removing sacrificial gate structures, and with releasing the active nanolayers 110 within the nanosheet stacks by removing the sacrificial nanolayers. At block 210, method 200 may continue with forming the respective replacement gate structure 128 within the opening formed by the removal of the sacrificial gate structure. Further, at block 210, method 200 may continue with forming the frontside contact ILD, with forming frontside contacts 124, and with forming frontside BEOL network 126.

At block 212 method 200 may continue with partially removing the substrate structure 102, with forming and patterning the first backside contact layer 140, with forming the backside contact placeholder 150, with forming and patterning the second backside contact layer 160, with removing the backside contact placeholder 150, and with forming the confined backside contact 170.

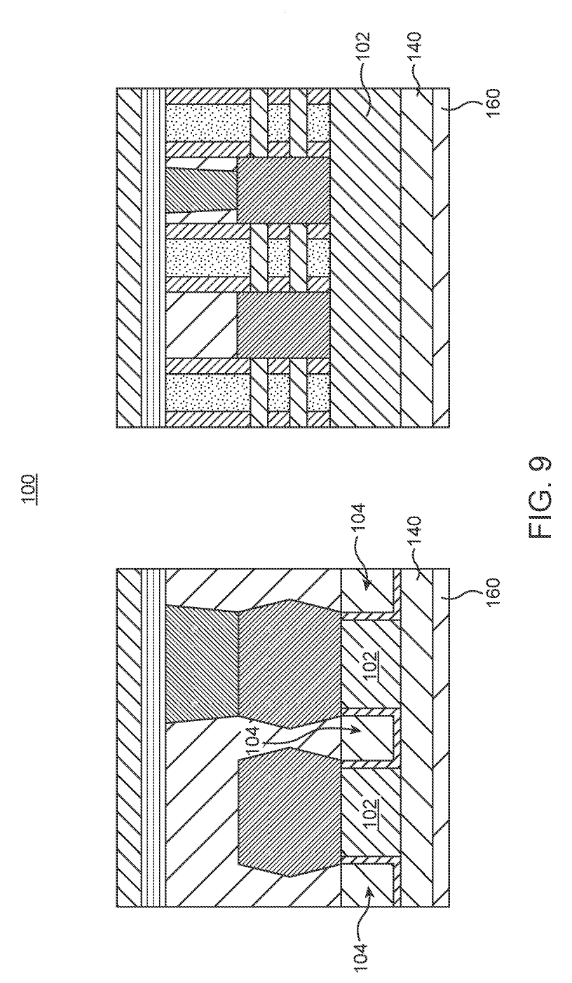

FIG. 9 depicts cross-sectional views of a semiconductor IC device 300 after fabrication operations, in accordance with embodiments of the present disclosure. The depicted example of semiconductor IC device 300 may be formed with similar fabrication techniques, described in relation to FIG. 2 and in FIG. 3. Subsequently, and in the depicted fabrication stages, the first backside contact layer 140 may be formed and the second backside layer 160 may be formed. For example, the first backside contact layer 140 may be formed on the backside of the semiconductor IC device (e.g., the respective backside surfaces of the STI regions 104 and the substrate structure 102). Subsequently, the second backside contact layer 160 may be formed on the backside of the first backside contact layer 140. The formation of the first backside contact layer 140 and the second backside contact layer 160 may be accomplished by techniques as described herein and are not repeated here.

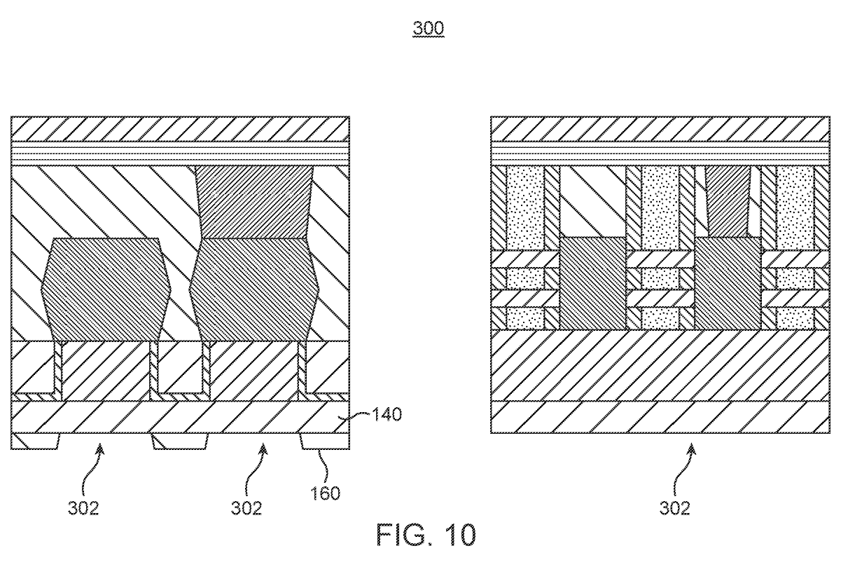

FIG. 10 depicts cross-sectional views of the semiconductor IC device 300 after fabrication operations, in accordance with embodiments of the present disclosure. In the depicted fabrication stages, backside trench openings 302 may be formed within the second backside contact layer 160.

The backside trench openings 302 may be formed by lithography and etch process(es). In such process(es), a mask (not shown) may be applied to the backside of the second backside contact layer 160 and patterned. An etch may form the backside trench openings 302, such a trenches, in the patterned mask by sequentially exposing respective underlying portions of the second backside contact layer 160, while other protected portions of semiconductor IC device 100 may be protected and retained. The etch may stop or otherwise have selectivity to the first backside contact layer 140.

Due to the increased pitch between adjacent backside trench openings 302, alignment of such trenches or openings may be relatively improved. For clarity, the formation of backside trench openings 302 may expose or otherwise gouge the backside of the second backside contact layer 160 in line therewith.

The second backside contact layer 160 may be formed by etch process(es) that may remove the exposed portions of the second backside layer 160. In such process(es), etching processes can have etching parameters that can be tuned, such as etchants used, etching temperature, etching solution concentration, etching pressure, source power, RF bias voltage, RF bias power, etchant flow rate, to promote desired material removal (e.g., second backside contact layer 160) and desired material retention (e.g., first backside contact layer 140).

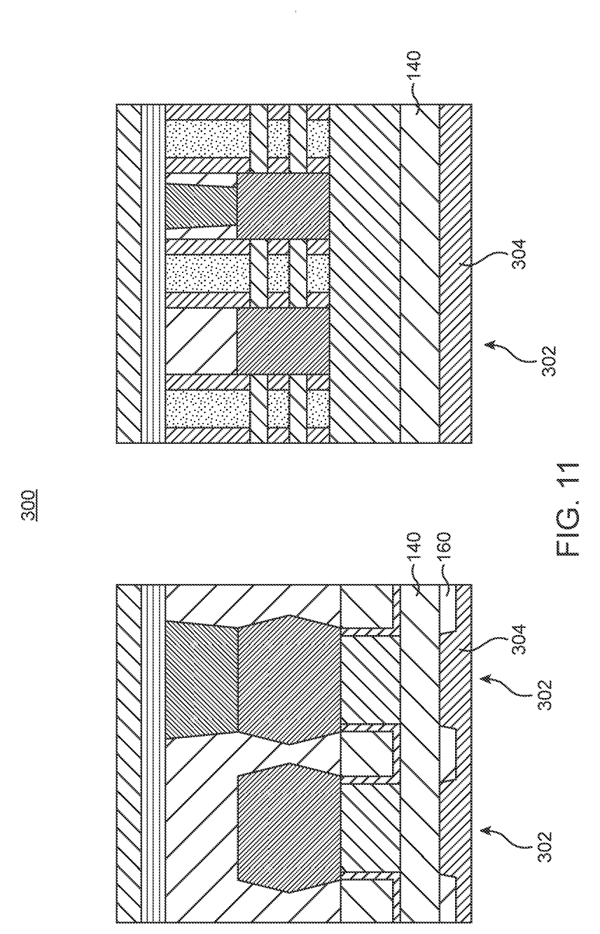

FIG. 11 depicts cross-sectional views of the semiconductor IC device 300 after fabrication operations, in accordance with embodiments of the present disclosure. In the depicted fabrication stages, a sacrificial liner 304 layer may be formed within the backside trench openings 302 and upon the backside of the semiconductor IC device 300. The sacrificial liner 304 layer may be formed of a sacrificial material, such as an organic planarization layer, or the like. The formation of the sacrificial liner 304 layer may be accomplished by techniques as described herein and are not repeated here.

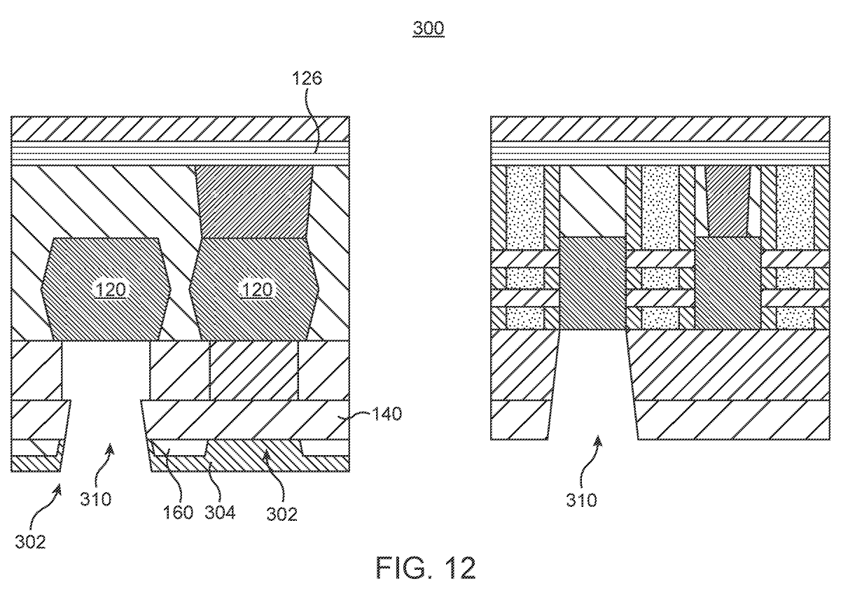

FIG. 12 depicts cross-sectional views of the semiconductor IC device 300 after fabrication operations, in accordance with embodiments of the present disclosure. In the depicted fabrication stages, the sacrificial liner 304 layer and confined backside contact openings 310 may be formed.

The confined backside contact openings 310 may be formed by lithography and etch process(es). In such process(es), a mask (not shown) may be applied to the backside of the sacrificial liner 304 layer and patterned. One or more series of etchant(s) may be exposed through the openings in the in the patterned mask to sequentially expose respective portions of the underlying respective portion(s) of various backside sacrificial liner 304 layer, the first backside layer 104, and the substrate structure 120, while other protected portions of semiconductor IC device 300 may be protected and retained. The backside sacrificial liner 304 within the backside trench openings 302 of the second backside layer 160 may adequately protect the geometry of the contact openings 302 during these progressive etching stages to limit lateral etching that may subsequently cause undesired electrical shorting.

The etch processes to form the confined backside contact openings 310 may at least expose an associated in line S/D region 120. In such process(es), etching processes can have etching parameters that can be tuned, such as etchants used, etching temperature, etching solution concentration, etching pressure, source power, RF bias voltage, RF bias power, etchant flow rate, to promote desired material removal and desired material retention. For example, the confined backside contact openings 310 may formed by removing the appropriate portion of the first backside layer 140, the associated in line substrate structure 102 selective to the material of the STI region(s) 104. The etch may be timed or otherwise controlled to remove the substrate structure 102 while retaining the associated substrate structure 102. Subsequently, the backside sacrificial liner 304 may be removed.

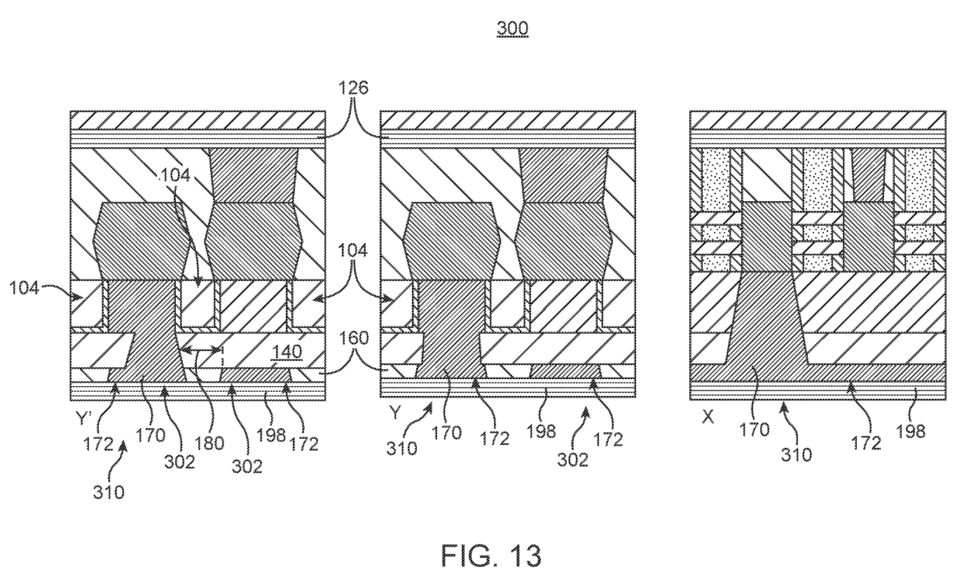

FIG. 13 depicts cross-sectional views of the semiconductor IC device 100 after fabrication operations, in accordance with embodiments of the present disclosure. In the depicted fabrication stages, confined backside contacts 170 and an adjacent backside rail 172 may be formed and backside BEOL network 198 may be formed. The formation of the confined backside contacts 170, the adjacent backside rail 172, and the backside BEOL network 198 may be accomplished by techniques as described herein and are not repeated here.

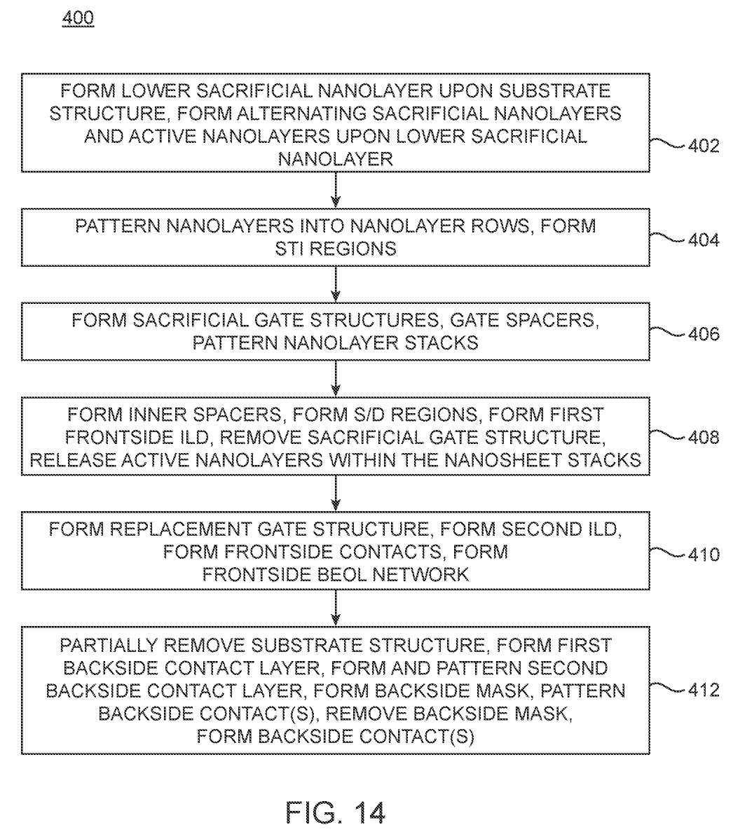

FIG. 14 depicts a flow diagram illustrating method 400 to fabricate a semiconductor IC device, such as semiconductor IC device 300. The depicted fabrication operations of method 400 are illustrated and described above with reference to one or more of FIG. 3 and FIG. 4 and FIG. 9 through FIG. 13 of the drawings, which describe the fabrication of semiconductor IC device 300, though the fabrication operations described in method 200 may be used to fabricate other types of semiconductor IC devices. The method 400 depicted herein is illustrative. There can be many variations to the diagram or operations described therein without departing from the spirit of the embodiments. For instance, the operations can be performed in a differing order, or operations can be added, deleted, or modified.

At block 402, method 400 may begin with forming alternating sacrificial nanolayers and active nanolayers 110 the substrate structure 102. At block 404, method 400 may continue with patterning the nanolayers into nanolayer rows and with forming STI regions 104 between the nanolayer rows. At block 406, method 400 may continue with forming sacrificial gate structures, with forming gate spacers 114, and with patterning the nanolayer rows into nanolayer stacks.

At block 408, method 400 may continue with indenting the sacrificial nanolayers within the nanolayer stacks and with forming inner spacers 112 within the associated void formed by the partial removal of the sacrificial nanolayers. Further at block 408, method 400 may continue with forming S/D regions 120, with forming ILD 122, with removing sacrificial gate structures, and with releasing the active nanolayers 110 within the nanosheet stacks by removing the sacrificial nanolayers. At block 410, method 400 may continue with forming the respective replacement gate structure 128 within the opening formed by the removal of the sacrificial gate structure. Further, at block 410, method 400 may continue with forming the frontside contact ILD, with forming frontside contacts 124, and with forming frontside BEOL network 126.

At block 412 method 400 may continue with partially removing the substrate structure 102, with forming the first backside contact layer 140, with forming the second backside contact layer 140, with patterning the second backside contact layer 160, form and pattern sacrificial mask 304, patterning the confined backside contact openings 310, removing the sacrificial mask 304, and with forming the confined backside contact 170.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a transistor comprising a plurality of channels, a gate around each of the plurality of channels, and a first source/drain (S/D) region between a first shallow trench isolation (STI) region and a second STI region;
a retained semiconductor substrate structure below the transistor; and
a confined backside contact comprising:
an upper portion in direct contact with the retained semiconductor substrate structure and in direct contact with the first S/D region; and
a lower portion in direct contact with the upper portion.

2. The semiconductor IC device of claim 1, wherein a backside surface of the upper portion is substantially coplanar with a backside surface of the retained semiconductor substrate structure.

3. The semiconductor IC device of claim 2, wherein the backside surface of the upper portion is substantially coplanar with respective backside surfaces of the first STI region and the second STI region.

4. The semiconductor IC device of claim 3, further comprising:
a first backside dielectric layer upon the backside surface of the retained semiconductor substrate structure and directly upon the respective backside surfaces of the first STI region and the second STI region.

5. The semiconductor IC device of claim 4, wherein the upper portion is directly connected to the first STI region and directly connected to the second STI region.

6. The semiconductor IC device of claim 5, wherein the lower portion is directly connected to the first backside dielectric layer.

7. The semiconductor IC device of claim 1, wherein the lower portion is in line with the upper portion.

8. The semiconductor IC device of claim 1, wherein the lower portion is offset from the upper portion.

9. The semiconductor IC device of claim 1, wherein a horizontal depth of the upper portion is greater than a horizontal depth of the lower portion at an interface of the upper portion and the lower portion.

10. The semiconductor IC device of claim 9, wherein a horizontal length of the upper portion is smaller than a horizontal length of the lower portion at the interface of the upper portion and the lower portion.

11. A semiconductor integrated circuit (IC) device comprising:
a retained semiconductor substrate structure;
a first isolation region comprising a first shallow trench isolation (STI) region and a first portion of a backside dielectric layer in direct contact with a backside of the first STI region;
a second isolation region comprising a second STI region and a second portion of the backside dielectric layer in direct contact with a backside of the second STI region, wherein the first STI region and the second STI region have etch selectivity to the backside dielectric layer; and
a confined backside contact comprising:
an upper portion in direct contact with the retained semiconductor substrate structure, in direct contact with the first STI region, and in direct contact with the second STI region; and
a lower portion in direct contact with the first backside isolation region and in direct contact with the second backside isolation region.

12. The semiconductor IC device of claim 11, wherein a backside surface of the upper portion is substantially coplanar with a backside surface of the retained semiconductor substrate structure.

13. The semiconductor IC device of claim 12, wherein the backside surface of the upper portion is substantially coplanar with respective backside surfaces of the first STI region and the second STI region.

14. The semiconductor IC device of claim 13, further comprising:
a backside-rail dielectric layer upon the backside surface of the backside dielectric layer, wherein the backside-rail dielectric has etch selectivity to the backside dielectric layer.

15. The semiconductor IC device of claim 14, wherein confined backside contact further comprises:
a backside rail directly connected to the lower portion within the backside-rail dielectric layer.

16. The semiconductor IC device of claim 11, wherein the lower portion is in line with the upper portion.

17. The semiconductor IC device of claim 11, wherein the lower portion is offset from the upper portion.

18. The semiconductor IC device of claim 11, wherein a horizontal depth of the upper portion is greater than a horizontal depth of the lower portion at an interface of the upper portion and the lower portion.

19. The semiconductor IC device of claim 18 wherein there is no interfacial resistance across the interface of the upper portion and the lower portion.

20. A semiconductor integrated circuit (IC) device comprising:
an isolation region between a first transistor and a second transistor, the isolation region comprising a shallow trench isolation (STI) region and a dual-layered dielectric region in direct contact with a backside of the first STI region; and
a confined backside contact comprising:
an upper portion in direct contact with a sidewall of the first STI region and wherein a backside surface of the upper portion is substantially coplanar with a backside surface of the STI region; and
a lower portion in direct contact with a sidewall of the dual-layered dielectric region and in direct contact with the backside of the upper portion.
